(19) United States
(12) Patent Application Publication
(10) Pub. No.: US 2024/0429076 A1
(43) Pub. Date: Dec. 26, 2024

(54) WAFER PROCESSING APPARATUS

(71) Applicant: DISCO CORPORATION, Tokyo (JP)

(72) Inventor: Kensuke FURUTA, Tokyo (JP)

(21) Appl. No.: 18/746,282

(22) Filed: Jun. 18, 2024

(30) Foreign Application Priority Data
Jun. 21, 2023 (JP) 2023-101707

(51) Int. Cl. H01L 21/67; H01L 21/68; H01L 21/683

(52) U.S. Cl. CPC H01L 21/67253; H01L 21/68; H01L 21/6838

(57) ABSTRACT

A wafer processing apparatus includes a cutting unit that supports, in a manner allowing rotation, a cutting blade for removing a chamfered portion of a wafer held under suction on a chuck table, a height measuring instrument that measures the height of the upper surface of the wafer, and a controller. The controller includes a cutting depth storage section that stores a target cutting depth in the Z-axis direction of the chamfered portion to be removed from the top surface of the wafer, a top surface coordinate storage section that measures the Z-axis coordinate of the top surface by actuating the height measuring instrument and stores the Z-axis coordinate, and a chamfered portion removing operation section that cutting-feeds the cutting unit in the Z-axis direction and removes the chamfered portion by actuating the Z-axis feed mechanism in reference to the target cutting depth and the Z-axis coordinate.

### BACKGROUND OF THE INVENTION

### Field of the Invention

The present invention relates to a processing apparatus for a wafer, the wafer including, on a top surface thereof, a device region having a plurality of devices so formed as to be demarcated by a plurality of intersecting planned dividing lines and a peripheral surplus region surrounding the device region, and the wafer having a chamfered portion at an outer circumferential edge of the peripheral surplus region.

### Description of the Related Art

A wafer having a plurality of devices such as integrated circuits (ICs) or large scale integration (LSI) circuits formed on a top surface thereof in such a manner as to be demarcated by a plurality of intersecting planned dividing lines is formed to a predetermined thickness by an undersurface of the wafer being ground, and is then divided into individual device chips by a cutting apparatus. The divided device chips are used in electric apparatuses such as mobile telephones or personal computers.

A grinding apparatus includes a chuck table that holds the wafer, a grinding unit that includes, in a manner allowing rotation, a grinding wheel annularly provided with a plurality of grinding stones for grinding the wafer held on the chuck table, a feed mechanism that grinding-feeds the grinding unit, and a thickness measuring instrument that measures the thickness of the wafer. The grinding apparatus can process the wafer to a desired thickness by grinding the undersurface of the wafer.

However, a chamfered portion is formed at the outer circumference of the wafer. Hence, when the wafer is thinned by the undersurface of the wafer being ground, the chamfered portion at an outer circumferential edge of the wafer becomes a sharp knife edge, thus causing a risk that a crack may occur from the outer circumference, develop into the device region, and damage the devices, and that an operator may be injured.

Accordingly, a technology of removing the chamfered portion formed at the outer circumferential edge before the grinding of the undersurface of the wafer has been presented by the present applicant (see Japanese Patent Laid-open No. 2016-96295, for example).

### SUMMARY OF THE INVENTION

In a case of a laminated wafer (Bonded Wafer) in which two wafers are laminated, a chamfered portion on the outer circumference side of one wafer whose undersurface is to be ground may be removed by a cutting blade before the lamination of the two wafers, and thereafter the top surface of the one wafer from which the chamfered portion has been removed may be laminated to another wafer. At that time, when the chamfered portion of the one wafer is removed in whole, alignment using the shape of the outer circumference as a reference cannot be performed, making it difficult to perform accurate alignment when laminating the two wafers. Thus, half or more of the chamfered portion of the one wafer needs to be left. Further, when the chamfered portion is to be removed by the cutting blade, there is also a necessity of removing the chamfered portion with a cutting depth slightly exceeding a finished thickness obtained by grinding the undersurface of the one wafer. It is hence desired to remove the chamfered portion with high accuracy.

However, there is a problem of a difficulty in removing the chamfered portion at the outer circumference of the wafer precisely with a desired cutting depth due to an effect of wear in the cutting blade, a distortion of the cutting blade caused by heat generation of the cutting blade as cutting processing is performed, or the like.

It is accordingly an object of the present invention to provide a wafer processing apparatus that can control with high accuracy a cutting depth at a time of removing a chamfered portion even when there is wear in a cutting blade, a distortion of the cutting blade due to heat generation of the cutting blade, or the like.

In accordance with an aspect of the present invention, there is provided a processing apparatus for a wafer, the wafer including, on a top surface of the wafer, a device region having a plurality of devices so formed as to be demarcated by a plurality of intersecting planned dividing lines and a peripheral surplus region surrounding the device region, and the wafer having a chamfered portion formed at an outer circumferential edge of the peripheral surplus region, the processing apparatus including a chuck table that has a holding surface defined by an X-axis and a Y-axis and configured to suck and hold the wafer and that is configured to be rotatable, a cutting unit that includes a spindle extending in a Y-axis direction, the spindle being configured to support, in a manner allowing rotation, a cutting blade configured to remove the chamfered portion of the wafer held under suction on the chuck table, a positioning unit configured to perform positioning such that an extending direction of the spindle passes through a rotational center of the chuck table, a Z-axis feed mechanism configured to processing-feed the cutting unit in a Z-axis direction perpendicular to the holding surface, a height measuring instrument configured to measure a height of an upper surface of the wafer held under suction on the chuck table, and a controller, the controller including a cutting depth storage section configured to store a target cutting depth in the Z-axis direction of the chamfered portion to be removed from the top surface of the wafer held under suction on the chuck table, a top surface coordinate storage section configured to measure a Z-axis coordinate of the top surface of the wafer by actuating the height measuring instrument, and store the Z-axis coordinate, and a chamfered portion removing operation section configured to cutting-feed the cutting unit in the Z-axis direction and remove the chamfered portion by actuating the Z-axis feed mechanism in reference to the target cutting depth stored in the cutting depth storage section and the Z-axis coordinate stored in the top surface coordinate storage section.

Preferably, the controller further includes a removal surface height storage section configured to, after the chamfered portion removing operation section removes the chamfered portion from an outer circumference of the wafer, measure a Z-axis coordinate of a removal surface at the outer circumference of the wafer available after the removal of the chamfered portion, by actuating the height measuring instrument, and store the Z-axis coordinate of the removal surface, and a correcting section configured to obtain an actual cutting depth in reference to a difference between the Z-axis coordinate of the top surface of the wafer stored in the top surface coordinate storage section and the Z-axis coordinate of the removal surface stored in the removal surface height storage section, and maintain the target cutting depth when the actual cutting depth coincides with the target cutting depth stored in the cutting depth storage section, or calculate a difference between the target cutting depth and the actual cutting depth and set the difference as a cutting depth correction value when the actual cutting depth does not coincide with the target cutting depth, and the controller adds the correction value to the target cutting depth in the chamfered portion removing operation section, and cutting-feeds the cutting unit in the Z-axis direction by actuating the Z-axis feed mechanism.

The wafer processing apparatus according to the present invention can accurately cut into the chamfered portion from the top surface of the wafer such that a finished thickness obtained by grinding the undersurface of the wafer is slightly exceeded.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a general perspective view of a cutting apparatus according to a present embodiment;

FIG. 2 is a conceptual diagram illustrating a configuration of a controller disposed in the cutting apparatus illustrated in FIG. 1;

FIG. 3 is a perspective view illustrating a manner in which a wafer is mounted onto a chuck table of the cutting apparatus;

FIG. 4 is a perspective view illustrating a manner in which the height of the top surface of the wafer is measured by a height measuring instrument;

FIG. 5 is a side view illustrating the manner in which the height of the top surface of the wafer is measured by the height measuring instrument illustrated in FIG. 4;

FIG. 6 is a perspective view illustrating a manner in which a cutting unit is positioned at the outer circumference of the wafer held on the chuck table;

FIG. 7 is a perspective view illustrating a manner of cutting processing for removing a chamfered portion of the wafer;

FIG. 8A is a side view illustrating, on an enlarged scale, a part of the cutting processing illustrated in FIG. 7;

FIG. 8B is a side view illustrating a manner in which a removal surface is formed by the chamfered portion being removed by the cutting processing illustrated in FIG. 8A;

FIG. 9 is a side view illustrating a manner in which the height of the removal surface at the outer circumference of the wafer illustrated in FIGS. 8A and 8B is measured; and

FIG. 10 is a flowchart of a control program executed by a correcting section of the controller illustrated in FIG. 2.

### DETAILED DESCRIPTION OF THE PREFERRED EMBODIMENT

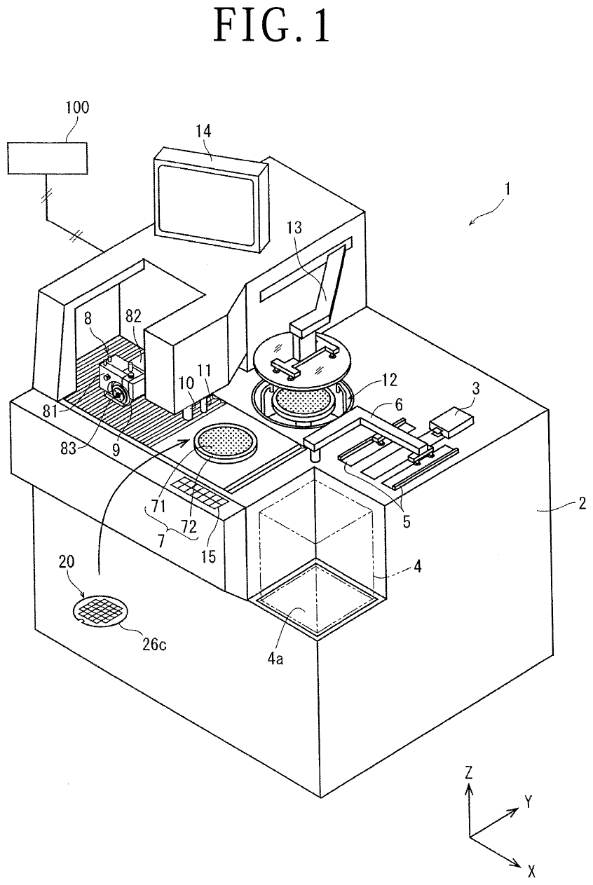

A wafer processing apparatus according to an embodiment of the present invention will hereinafter be described in detail with reference to the accompanying drawings. FIG. 1 illustrates a cutting apparatus 1 as an example of the wafer processing apparatus according to the present invention. The cutting apparatus 1 has a housing 2 in a substantially rectangular parallelepipedic shape. The cutting apparatus 1 is provided with a cassette 4 (indicated by a chain double-dashed line) mounted on a cassette table 4a of the housing 2; a loading and unloading mechanism 3 that unloads a wafer 20 from the cassette 4 onto a temporary placement table 5; a transporting mechanism 6 having a swing arm that transports the wafer 20 unloaded onto the temporary placement table 5 to a chuck table 7; a cutting unit 8 to which a cutting blade 9 that subjects the wafer 20 held on the chuck table 7 to processing is rotatably fitted; an alignment unit 10 for imaging the wafer 20 held on the chuck table 7 described above, and detecting a region to be processed by the cutting unit 8; height detecting instrument 11 for detecting the height of the upper surface of the wafer 20 held on the chuck table 7, the height detecting instrument 11 being so disposed as to be adjacent in a Y-axis direction to the alignment unit 10; a cleaning transporting mechanism 13 that transports the wafer 20 to a cleaning apparatus 12 from a loading/unloading position at which the chuck table 7 is positioned in FIG. 1; a display unit 14 that constitutes a touch panel disposed on an upper portion of the housing 2; an input unit 15; and a controller 100 that controls various actuating units of the cutting apparatus 1. Incidentally, while the controller 100 is depicted on the outside of the housing 2 for the convenience of description, the controller 100 is in reality housed within the housing 2.

The chuck table 7 includes a suction chuck 71 that forms a holding surface defined by an X-axis indicated by an arrow X in the figure and a Y-axis indicated by an arrow Y, the Y-axis being orthogonal to the X-axis, and that is formed by a permeable porous member; and a frame body 72 that surrounds the suction chuck 71. In addition, the chuck table 7 is configured to be rotatable. The chuck table 7 is connected to suction means not illustrated in the figure via the frame body 72. A negative pressure is generated on the upper surface of the suction chuck 71 by the suction means being actuated. The wafer 20 can thereby be held under suction on the upper surface of the suction chuck 71.

The cutting unit 8 includes a spindle 83 that supports, in a manner allowing rotation, the cutting blade 9 for removing a chamfered portion 26c formed in an outer circumferential edge portion of the wafer 20 held under suction by the chuck table 7 described above, and that extends in the Y-axis direction. The cutting unit 8 also includes a spindle housing 82 that supports, in a manner allowing rotation, the spindle 83 and a blade cover 81 that is disposed at a distal end of the spindle housing 82 and that covers the cutting blade 9.

Provided within the housing 2 are an X-axis feed mechanism that processing-feeds the chuck table 7 in the X-axis direction, a Y-axis feed mechanism that indexing-feeds the cutting unit 8 in the Y-axis direction orthogonal to the X-axis direction, a Z-axis feed mechanism that processing-feeds the cutting unit 8 by moving the cutting unit 8 in a Z-axis direction (upward-downward direction), which is a direction orthogonal to the X-axis direction and the Y-axis direction, and is perpendicular to the suction chuck 71 forming the holding surface of the chuck table 7, and a rotational driving mechanism that rotates the chuck table 7 (none is illustrated). The X-axis feed mechanism, the Y-axis feed mechanism, the Z-axis feed mechanism, and the rotational driving mechanism described above are controlled by the controller 100. The X-axis feed mechanism in the present embodiment functions as positioning means for performing positioning such that the extending direction of the spindle 83 of the cutting unit 8 passes through a rotational center of the chuck table 7.

The controller 100 is constituted by a computer. The controller 100 includes a central processing unit (CPU) that performs arithmetic processing according to a control program, a read-only memory (ROM) that stores the control program and the like, a readable and writable random access memory (RAM) for temporarily storing a detected detection value, an arithmetic result, and the like, an input interface, and an output interface (details are not illustrated). The controller 100 is connected with various actuating units of the cutting apparatus 1, and is connected with the display unit 14 and the input unit 15 described above. An operator can give an instruction to start or end processing or input processing conditions or the like by operating the display unit 14 or the input unit 15.

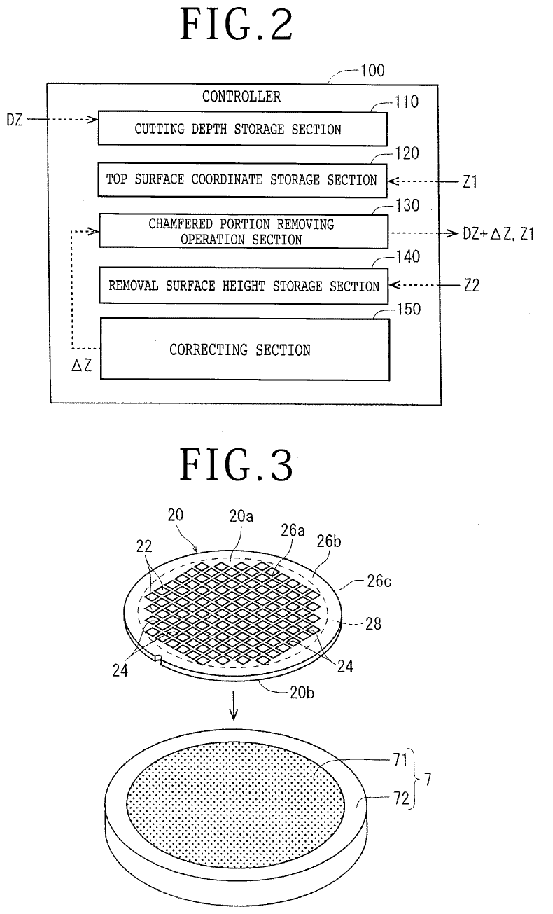

As illustrated in FIG. 2, the controller 100 includes a cutting depth storage section 110 that stores a target cutting depth DZ in the Z-axis direction of a chamfered portion to be removed from a top surface of the wafer 20 held under suction on the chuck table 7, a top surface coordinate storage section 120 that measures a Z-axis coordinate Z1 of the top surface of the wafer 20 by actuating a height measuring instrument 11, and stores the Z-axis coordinate Z1, and a chamfered portion removing operation section 130 that actuates the Z-axis feed mechanism described above by sending an actuating signal to the Z-axis feed mechanism in reference to the target cutting depth DZ stored in the cutting depth storage section 110 and the Z-axis coordinate Z1 stored in the top surface coordinate storage section 120, and removes the chamfered portion 26c of the wafer 20 by cutting-feeding the cutting unit 8 in the Z-axis direction. Incidentally, the chamfered portion removing operation section 130 illustrated in the figure adds a correction value ΔZ to be described later to the target cutting depth DZ, and controls the Z-axis feed mechanism. However, the correction value ΔZ is zero in an initial state in which the cutting blade 9 is new.

Further, the controller 100 in the present embodiment includes a removal surface height storage section 140 that, after the chamfered portion removing operation section 130 removes the chamfered portion 26c of the wafer 20 by actuating the cutting unit 8, measures the height (Z-axis coordinate Z2) of a removal surface of the chamfered portion 26c of the wafer 20 available after the removal of the chamfered portion 26c, by actuating the height measuring instrument 11, and stores the height (Z-axis coordinate Z2), and a correcting section 150 that obtains an actual cutting depth SZ in reference to a difference between the Z-axis coordinate Z1 of the top surface stored in the top surface coordinate storage section 120 and the Z-axis coordinate Z2 stored in the removal surface height storage section 140, and maintains the target cutting depth DZ when the actual cutting depth SZ coincides with the target cutting depth DZ stored in the cutting depth storage section 110, or calculates a difference AZ between the target cutting depth DZ at a time of the removal of the chamfered portion 26c and the actual cutting depth SZ and sets the difference AZ as a cutting depth correction value when the actual cutting depth SZ does not coincide with the target cutting depth DZ.

The cutting apparatus 1 according to the present embodiment generally has the configuration as described above. Functions as well as actions and effects of the cutting apparatus 1 described above, particularly the controller 100, will be described below.

FIG. 3 illustrates the wafer 20 that is yet to be processed in the present embodiment. The wafer 20 illustrated in the figure is, for example, a semiconductor (for example, silicon) wafer that has a diameter of 300 mm and a thickness of 700 μm, and which has a plurality of devices 22 formed on a top surface 20a in such a manner as to be demarcated by a plurality of intersecting planned dividing lines 24. A plurality of wafers 20 are housed in the cassette 4. As illustrated in the figure, the wafer 20 includes a device region 26a in which the devices 22 are formed, a peripheral surplus region 26b that surrounds the device region 26a, and the chamfered portion 26c chamfered at the outer circumferential edge of the peripheral surplus region 26b. In FIG. 3, an annular imaginary line 28 (indicated by a broken line) which divides the device region 26a and the peripheral surplus region 26b from each other is depicted. Yet, this imaginary line 28 is provided for the convenience of description, and is not actually formed on the top surface 20a of the wafer 20. A length L in a radial direction from the outer circumferential edge to be removed in the chamfered portion 26c of the wafer 20 is 3.0 mm, and is stored in the controller 100 in advance. In addition, the target cutting depth DZ (for example, 300 μm) in the Z-axis direction of the chamfered portion 26c to be removed from the top surface 20a of the wafer 20 held under suction by the chuck table 7 is input by the operator in advance by using the display unit 14 or the input unit 15 described above, and is stored in the cutting depth storage section 110.

In the present embodiment, the length L in the radial direction from the outer circumferential edge to be removed in the chamfered portion 26c is 3.0 mm, as described above. Meanwhile, the cutting blade 9 which is so formed as to have, as a width (thickness) thereof, a thickness of 3.3 mm, which is larger than the length L in the radial direction from the outer circumferential edge to be removed, is prepared. The cutting blade 9 is, for example, obtained by solidifying diamond abrasive grains with a bonding material, and performing sintering. The bonding material is preferably selected from one of a resin bond, a vitrified bond, and a metal bond, for example.

At a time of performing the processing of removing the chamfered portion 26c of the wafer 20 illustrated in FIG. 3 by the cutting apparatus 1 illustrated in FIG. 1, the loading and unloading mechanism 3 unloads the wafer 20 from the cassette 4 of the cutting apparatus 1 described with reference to FIG. 1 and temporarily places the wafer 20 on the temporary placement table 5, and the transporting mechanism 6 is actuated to suck the wafer 20, transport the wafer 20 from the temporary placement table 5 to the chuck table 7, and mount the wafer 20 on the chuck table 7. At this time, as illustrated in FIG. 3, the wafer 20 is mounted on the chuck table 7 in a state in which an undersurface 20b of the wafer 20 is oriented downward. A negative pressure is generated on the suction chuck 71 by the suction means not illustrated being actuated. The wafer 20 is thereby held under suction on the suction chuck 71.

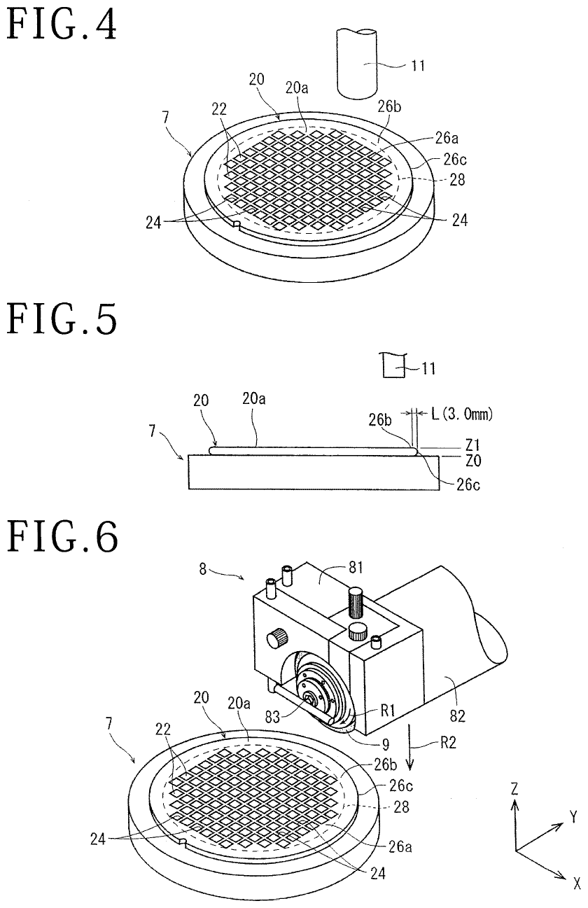

After the wafer 20 is held under suction on the chuck table 7 as described above, the X-axis feed mechanism described above is actuated to position the wafer 20 directly below the alignment unit 10 described above together with the chuck table 7. Alignment which images the wafer 20 and detects the center of the wafer 20 and the position of a region in which the length in the radial direction from the outer circumferential edge of the chamfered portion 26c to be removed in the peripheral surplus region 26b is L (3.0 mm) is performed. The position information is stored in a predetermined storage unit of the controller 100. Further, as illustrated in FIGS. 4 and 5, the X-axis feed mechanism described above is actuated to position the height detecting instrument 11 above the top surface 20a in the region of the chamfered portion 26c to be removed in the wafer 20. The Z-axis coordinate Z1 which indicates the height of the top surface 20a with respect to a top surface height Z0 (measured in advance and stored in the controller 100) of the chuck table 7, the top surface height Z0 serving as a reference, is measured. The Z-axis coordinate Z1 is then stored in the top surface coordinate storage section 120 of the controller 100. A difference between the top surface height Z0 of the chuck table 7 and the Z-axis coordinate Z1 of the top surface 20a in the region of the chamfered portion 26c is the thickness of the wafer 20.

Next, the X-axis feed mechanism of the cutting apparatus 1 described above is actuated in reference to the position information concerning the processing region detected by the alignment described above, to perform positioning such that the extending direction of the spindle 83 of the cutting unit 8 passes through the rotational center of the chuck table 7 (which rotational center is also the center of the wafer 20), as illustrated in FIG. 6. Then, the Y-axis feed mechanism described above is actuated to position a region to be removed in the chamfered portion 26c of the wafer 20 directly below the cutting blade 9 fitted to the cutting unit 8. At this time, the cutting blade 9 is positioned at a position coinciding with the length L (3.0 mm) in the radial direction from the outer circumferential edge of the chamfered portion 26c to be removed.

Then, the cutting blade 9 is rotated in a direction indicated by an arrow R1 at a predetermined rotational speed (for example, 30000 rpm), and the chamfered portion removing operation section 130 is executed on the basis of the target cutting depth DZ stored in the cutting depth storage section 110 and the Z-axis coordinate Z1 of the top surface 20a in the region of the chamfered portion 26c, the Z-axis coordinate Z1 being stored in the top surface coordinate storage section 120. The Z-axis feed mechanism described above is actuated to lower the cutting unit 8 in a direction indicated by an arrow R2 in FIG. 6, and processing-feed the cutting blade 9 to the chamfered portion 26c of the wafer 20.

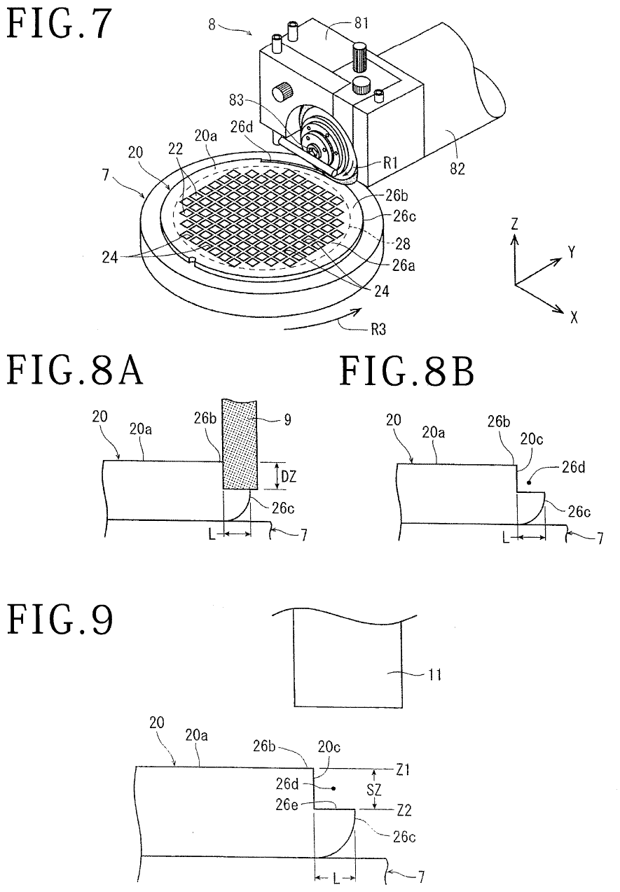

Together with the processing-feeding of the cutting blade 9 described above, as illustrated in FIG. 7, the chuck table 7 is rotated at least once in a direction indicated by an arrow R3 at a predetermined rotational speed (for example, 0.8 to 3 rpm). At this time, as illustrated in FIG. 8A, the cutting blade 9 is actuated according to the target cutting depth DZ (300 μm) in the region of the length L (3.0 mm) in the radial direction from the outer circumferential edge. As a result, as illustrated in FIG. 8B, the chamfered portion 26c formed at the outer circumferential edge of the peripheral surplus region 26b in the wafer 20 is annularly removed, and a chamfer removal portion 26d is formed. Incidentally, the above-described target cutting depth DZ is set according to the thickness of the wafer 20 to be finished by being ground from the undersurface 20b side by undersurface grinding processing (details thereof will be omitted) to be performed in a subsequent process. In the present embodiment, the wafer 20 is finished to a thickness of 250 μm by the undersurface 20b of the wafer 20 being ground by the undersurface grinding processing to be performed afterward. The target cutting depth DZ in the removal of the chamfered portion is accordingly set to 300 μm.

In the embodiment described above, the chamfered portion removing operation section 130 is executed in reference to the target cutting depth DZ stored in the cutting depth storage section 110 and the Z-axis coordinate Z1 of the top surface 20a in the region of the chamfered portion 26c, the Z-axis coordinate Z1 being stored in the top surface coordinate storage section 120. It is thus possible to accurately cut into the chamfered portion 26c from the top surface 20a of the wafer 20 such that the finished thickness obtained by grinding the undersurface of the wafer 20 is slightly exceeded.

It is to be noted that, while a cutting blade 9 formed with a thickness of 3.3 mm larger than the length L (3.0 mm) in the radial direction from the outer circumferential edge to be removed is prepared as the cutting blade 9 fitted to the cutting unit 8 in the embodiment described above, the present invention is not limited to this, and a cutting blade having a thickness less than 3.0 mm may be used. In that case, as in the foregoing, the chamfered portion 26c forming the outer circumferential edge of the peripheral surplus region 26b of the wafer 20 can be removed annularly with a width of the length L in the radial direction by cutting processing being performed while a cutting-in position being changed a plurality of times according to the thickness of the cutting blade 9.

The cutting apparatus 1 according to the present embodiment includes the removal surface height storage section 140 and the correcting section 150 described above. The cutting apparatus 1 can thus further improve processing accuracy at the time of removing the chamfered portion 26c.

After the chamfered portion 26c forming the outer circumferential edge of the peripheral surplus region 26b of the wafer 20 is annularly removed according to the target cutting depth DZ with the width of the length L in the radial direction from the outer circumferential edge, as described above, the X-axis feed mechanism described above is actuated to move the wafer 20, and position the chamfer removal portion 26d obtained after the removal of the chamfered portion 26c directly below the height measuring instrument 11, as illustrated in FIG. 9. Next, the height measuring instrument 11 is actuated to measure the Z-axis coordinate Z2 of a removal surface 26e as an upper surface of the chamfer removal portion 26d. The Z-axis coordinate Z2 is stored in the removal surface height storage section 140.

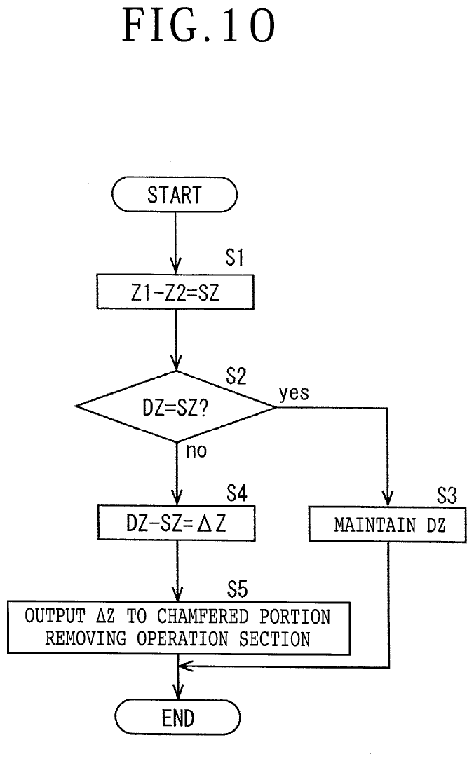

After the Z-axis coordinate Z2 of the removal surface 26e is measured and stored in the removal surface height storage section 140, as described above, the cutting depth correction value ΔZ is calculated by execution of the control program illustrated by a flowchart of FIG. 10 that is to be performed by the correcting section 150. A procedure for calculating the cutting depth correction value ΔZ will be described below with reference to FIG. 10.

First, after the control program illustrated by the flowchart of FIG. 10 is started (START), the actual cutting depth SZ is computed from a difference between the Z-axis coordinate Z1 of the top surface 20a of the wafer 20, the Z-axis coordinate Z1 being stored in the top surface coordinate storage section 120, and the Z-axis coordinate Z2 of the removal surface 26e (step S1).

Next, the procedure proceeds to step S2 to determine whether or not the actual cutting depth SZ coincides with the target cutting depth DZ described above (step S2). The determination of whether or not the actual cutting depth SZ and the target cutting depth DZ coincide with each other is not limited to determining whether or not the actual cutting depth SZ completely coincides with the target cutting depth DZ, and is preferably made with a certain range. For example, when step S2 is performed, DZ−SZ=ΔZ is computed, and whether or not the value of ΔZ is equal to or less than a predetermined value can be set as a condition for determining whether or not the actual cutting depth SZ and the target cutting depth DZ coincide with each other. The predetermined value can be set to 20 μm, for example. When the value of the ΔZ is equal to or less than 20 μm, processing can be performed with a substantially desired cutting depth, and a cutting depth exceeding the finished thickness formed by grinding processing to be performed in a subsequent process is ensured. Hence, when a determination of yes is made in step S2, the procedure proceeds to step S3, where the chamfered portion removing operation section 130 maintains the cutting depth at a time of making the cutting blade 9 cut in at the target cutting depth DZ, without setting ΔZ as a correction value. The flowchart is then ended (END).

When a determination of no is made in step S2, on the other hand, the procedure proceeds to step S4. It is to be noted that, while it is assumed that the actual cutting depth SZ and the target cutting depth DZ do not coincide with each other and the determination of no is made in step S2 due to such a cause as wear in the cutting blade 9 or a distortion occurring in the cutting blade 9 due to heat generation of the cutting blade 9 as cutting processing is performed, the present invention is not limited to this.

In step S4, ΔZ obtained by computing a difference (DZ−SZ) between the target cutting depth DZ and the actual cutting depth SZ is set as a correction value. Incidentally, in a case where DZ−SZ=ΔZ is already computed in step S2, ΔZ computed in step S2 can be set as the correction value as it is. Incidentally, in a case where the correction value ΔZ is already calculated and stored in the controller 100 before the flowchart is performed this time, an update is performed by using ΔZ obtained by performing the flowchart this time as a new correction value ΔZ.

After step S4 is performed as described above, the procedure proceeds to step S5, where the correction value ΔZ described above is communicated to the chamfered portion removing operation section 130. The flowchart is then ended (END). As illustrated in FIG. 2, when the correction value ΔZ computed by the correcting section 150 is communicated to the chamfered portion removing operation section 130, the cutting depth of the cutting processing to be performed by the next operation of the chamfered portion removing operation section 130 is Target Cutting Depth Dz+Correction Value ΔZ with respect to the Z-axis coordinate Z1 stored in the top surface coordinate storage section 120, and the cutting depth is thus corrected in reference to the correction value ΔZ. Incidentally, the wafer 20 that causes a determination that the correction of the cutting depth is necessary is not actually processed with the target cutting depth DZ, and is hence preferably subjected to the cutting processing for removing the chamfered portion 26c again in reference to the cutting depth to which the correction value ΔZ is added (DZ+ΔZ). In addition, when the cutting processing for removing the chamfered portion 26c is performed on the wafer 20 in reference to Cutting Depth DZ+Correction Value ΔZ as described above, the control program illustrated by the flowchart of FIG. 10 is preferably performed to check the difference between the actual cutting depth SZ and the target cutting depth DZ. After the target cutting depth DZ is corrected by the correction value ΔZ and the chamfered portion 26c of the wafer 20 held on the chuck table 7 is removed, as described above, the cleaning transporting mechanism 13 unloads the wafer 20 on the chuck table 7, and transports the wafer 20 to the cleaning apparatus 12, where the wafer 20 is cleaned and dried. The transporting mechanism 6 and the loading and unloading mechanism 3 are then actuated to house the wafer 20 in a predetermined position of the cassette 4.

Incidentally, the updating of the correction value ΔZ, which is performed by the correcting section 150 described above being actuated, can be performed in any timing, but is preferably performed in a periodic manner. The periodic manner may, for example, be each time the processing on one wafer 20 is completed, as described above, each time all of the wafers 20 housed in one cassette 4 are completed, or each time processing for one day is completed.

As described above, the target cutting depth DZ of the cutting processing to be performed by the chamfered portion removing operation section 130 is corrected by the correction value ΔZ described above. It is thus possible to form the chamfer removal portion 26d by removing the chamfered portion 26c of the wafer 20 with high accuracy even when there is an effect of wear in the cutting blade 9, a distortion of the cutting blade 9 due to heat, or the like.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus for a wafer, the wafer including, on a top surface of the wafer, a device region having a plurality of devices so formed as to be demarcated by a plurality of intersecting planned dividing lines and a peripheral surplus region surrounding the device region, and the wafer having a chamfered portion formed at an outer circumferential edge of the peripheral surplus region, the processing apparatus comprising:
a chuck table that has a holding surface defined by an X-axis and a Y-axis and configured to hold the wafer under suction and that is configured to be rotatable;
a cutting unit that includes a spindle extending in a Y-axis direction, the spindle being configured to support, in a manner allowing rotation, a cutting blade configured to remove the chamfered portion of the wafer held under suction on the chuck table;
a positioning unit configured to perform positioning such that an extending direction of the spindle passes through a rotational center of the chuck table;
a Z-axis feed mechanism configured to processing-feed the cutting unit in a Z-axis direction perpendicular to the holding surface;
a height measuring instrument configured to measure a height of an upper surface of the wafer held under suction on the chuck table; and
a controller,
the controller including
a cutting depth storage section configured to store a target cutting depth in the Z-axis direction of the chamfered portion to be removed from the top surface of the wafer held under suction on the chuck table,
a top surface coordinate storage section configured to measure a Z-axis coordinate of the top surface of the wafer by actuating the height measuring instrument, and store the Z-axis coordinate, and
a chamfered portion removing operation section configured to cutting-feed the cutting unit in the Z-axis direction and remove the chamfered portion by actuating the Z-axis feed mechanism in reference to the target cutting depth stored in the cutting depth storage section and the Z-axis coordinate stored in the top surface coordinate storage section.

2. The processing apparatus for the wafer according to claim 1, wherein
the controller further includes
a removal surface height storage section configured to, after the chamfered portion removing operation section removes the chamfered portion from an outer circumference of the wafer, measure a Z-axis coordinate of a removal surface at the outer circumference of the wafer available after the removal of the chamfered portion, by actuating the height measuring instrument, and store the Z-axis coordinate of the removal surface, and
a correcting section configured to obtain an actual cutting depth in reference to a difference between the Z-axis coordinate of the top surface of the wafer stored in the top surface coordinate storage section and the Z-axis coordinate of the removal surface stored in the removal surface height storage section, and maintain the target cutting depth when the actual cutting depth coincides with the target cutting depth stored in the cutting depth storage section, or calculate a difference between the target cutting depth and the actual cutting depth and set the difference as a cutting depth correction value when the actual cutting depth does not coincide with the target cutting depth, and
the controller adds the correction value to the target cutting depth in the chamfered portion removing operation section, and cutting-feeds the cutting unit in the Z-axis direction by actuating the Z-axis feed mechanism.

3. The processing apparatus for the wafer according to claim 2, wherein
the controller updates the correction value by periodically actuating the correcting section.
